(19) United States
(12) Patent Application Publication
(10) Pub. No.: US 2005/0110666 A1
(43) Pub. Date: May 26, 2005

(54) Current driving apparatus and method for fabricating the same

(75) Inventor: Yoshito Date, Shiga (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 10/994,368

(22) Filed: Nov. 23, 2004

(30) Foreign Application Priority Data
Nov. 26, 2003 (JP) 2003-396031

(51) Int. Cl. H03M 1/66; G09G 3/30

(52) U.S. Cl. 341/144; 345/78

(57) ABSTRACT

In a current driving apparatus for driving a display panel, allocation of some of transistors used for constructing current sources is exchanged between first and second DA converter circuits. For example, a current source corresponding to the most significant bit of the first DA converter circuit is composed of transistors disposed on the first, third, fifth and seventh rows of a first transistor group and transistors disposed on the second, fourth, sixth and eighth rows of a second transistor group adjacent to the first transistor group. Similarly, a current source corresponding to the most significant bit of the second DA converter circuit is composed of transistors disposed on the second, fourth, sixth and eighth rows of the first transistor group and transistors disposed on the first, third, fifth and seventh rows of the second transistor group.

### CROSS-REFERENCE TO RELATED APLICATIONS

This application claims priority under 35 U.S.C. §119 on Patent Application No. 2003-396031 filed in Japan on Nov. 26, 2003, the entire contents of which are hereby incorporated by reference.

### BACKGROUND OF THE INVENTION

The present invention relates to a current driving apparatus for driving what is called a current-drive type display panel, such as an organic EL panel or an LED panel, in which brightness is controlled in accordance with the quantity of current, and more particularly, it relates to a technique to reduce variation in a supply current among output terminals derived from a static factor.

A driver LSI for driving a current-drive type display panel includes a current driving apparatus that is provided with a large number of current sources by using a current mirror and outputs currents from these current sources added in accordance with display data for controlling gray scale display.

Recently, the screen size and refinement of flat display panels have been improved, and their thickness and weight have been reduced and the cost has been lowered. In such background, a display driver is required to have performance for increasing uniformity of display quality by reducing variation among output terminals. In current variation of a current mirror, static (statistical) variation includes variation caused through diffusion process of respective transistors and gate voltage variation caused by resistance of power interconnections, and dynamic variation is caused by charge injection from a display panel and instantaneous power fluctuation.

FIGS. 13A and 13B are diagrams for showing the architecture of a conventional current driving apparatus, and more specifically, FIG. 13A shows the structure of one output part included in the current driving apparatus, which is provided with a current additive DA converter circuit 50 of 6-bit performance. In this case, a display panel 55 to be controlled is assumed as an organic EL panel.

In FIG. 13A, the current additive DA converter circuit 50 includes a plurality of current sources 51a, 51b and 51c provided correspondingly to respective bits of an input signal (display data) and a switch group 52 composed of switches for selecting outputs of the respective current sources 51a through 51c in accordance with the input signal. Each of the current sources 51a through 51c includes transistors (of N-type in this case) in a given number according to the bits. Specifically, the current source 51a corresponding to the least significant bit includes one transistor, the current source 51b corresponding to the second bit includes two transistors, and the current source 51c corresponding to the most significant bit (that is, the sixth bit in this case) includes thirty-two transistors. These transistors are connected in parallel, and contract a current mirror together with transistors included in a current source circuit not shown. The outputs of the current sources selected by the switch group 52 are added to be supplied to the display panel 55. The display panel 55 receives the supplied current and produces gray scale display in accordance with the display data.

FIG. 13B is a layout diagram of an N-type transistor included in each current source. As shown in FIG. 13B, the source of the N-type transistor is grounded.

The architecture shown in FIG. 13A corresponds to one output, and a plurality of current additive DA converter circuits of FIG. 13A are arranged in an actual current driving apparatus. In general, approximately several hundreds of DA converter circuits are provided correspondingly to pixels of the display panel.

FIG. 14 shows an example of the arrangement of the plural DA converter circuits. In FIG. 14, DA converter circuits 60A, 60B, . . . , and 60C in the identical layout shape are arranged along the X direction as cell structures extending in the column direction. Each of the DA converter circuits 60A through 60C includes six current sources 61a through 61f respectively corresponding to bits of an input signal, and outputs of the current sources are selected by switches 62. The selected outputs of the current sources are added to be output from output terminals 63A through 63C.

The current source 61f corresponding to the most significant sixth bit includes thirty-two transistors TR, which are arranged in the form of a matrix of four in the X direction by eight in the Y direction in FIG. 14. Similarly, the current source 61e corresponding to the fifth bit includes sixteen transistors TR, which are arranged in the form of a matrix of four in the X direction by four in the Y direction, and the current source 61d corresponding to the fourth bit includes eight transistors TR, which are arranged in the form of a matrix of four in the X direction by two in the Y direction. The current source 61c corresponding to the third bit includes four transistors TR, the current source 61b corresponding to the second bit includes two transistors TR and the current source 61a corresponding to the first bit includes one transistor TR for outputting the minimum current output.

The conventional current driving apparatus, however, has the following problem:

In the conventional current driving apparatus, a plurality of current additive DA converter circuits are arranged along the X direction as shown in FIG. 14. Therefore, when the converter circuits are integrated as a semiconductor device, the device has a slim layout with a long and narrow appearance. In employing such a slim layout, when the respective current sources are constructed as current mirrors, the characteristics of the respective current mirrors are not always the same but are varied depending upon the positions of the transistors. This variation in the characteristic depending upon the position seems to be caused due to variation in implantation of an impurity into a wafer occurring in diffusion process, variation in thermal diffusion, variation in the thickness of a gate oxide film and the like. Although the characteristics of transistors close to one another are substantially the same, the characteristic variation is caused due to statistical fluctuation when transistors are away from each other by several tens μm through several nm.

Even when the identical gate voltage is supplied, this characteristic variation causes variation in current values output from the respective current sources. As a result, the current supplied from the current driving apparatus is largely varied among the output terminals as shown in FIG. 15. When such current variation occurs, display unevenness (stripe unevenness) is caused in the display panel, and thus, the display uniformity is largely spoiled.

### SUMMARY OF THE INVENTION

In consideration of the aforementioned conventional problem, an object of the invention is, in a current driving apparatus for driving a display panel, suppressing and improving display ununiformity derived from current value variation even when characteristics of transistors included in current sources of current additive DA converter circuits are varied.

In order to achieve the object, according to the present invention, current value variation is suppressed by averaging output current variation by exchanging, between current additive DA converter circuits, allocation of transistors used for constructing the DA converter circuits.

Specifically, the first current driving apparatus of this invention for driving a display panel in which display brightness is controlled in accordance with the quantity of current, includes a plurality of output terminals for supplying a current to the display panel; and a plurality of transistor groups respectively disposed correspondingly to the plurality of output terminals and respectively including a given number of transistors used for constructing current sources of a plurality of current additive DA converter circuits for respectively supplying currents to the plurality of output terminals, and a first current additive DA converter circuit that is at least one of the plurality of current additive DA converter circuits includes a first current source composed of transistors belonging to at least two or more transistor groups out of the plurality of transistor groups.

In the first current driving apparatus, the first current source of at least one first current additive DA converter circuit is composed of the transistors belonging to at least two transistor groups out of the plural transistor groups. Therefore, even when the characteristic is varied among the transistor groups, the characteristic variation is averaged for the performance of the first current source. Accordingly, the output current value can be prevented from being largely different from those of the other current sources, so that the display quality uniformity of the display panel can be improved.

In the first current driving apparatus, the first current source is preferably composed of transistors belonging to first and second transistor groups out of the plurality of transistor groups.

Furthermore, the first current source is preferably composed of M (wherein M is a natural number) transistors, and the M transistors preferably include M/2 transistors belonging to the first transistor group and M/2 transistors belonging to the second transistor group. Alternatively, the first transistor group and the second transistor group are preferably arranged adjacently to each other. Alternatively, the plurality of transistor groups are preferably arranged in rows, and the first transistor group and the second transistor group are preferably spaced from each other at an interval of a given number of transistor groups.

In the first current driving apparatus, each of the plurality of current additive DA converter circuits preferably includes a plurality of current sources provided correspondingly to respective bits of an input signal and each composed of a given number of transistors in the number according to a corresponding bit, and each of all or some of a plurality of current sources including the first current source provided in the first current additive DA converter circuit is preferably composed of transistors belonging to at least two or more transistor groups out of the plurality of transistor groups.

Furthermore, out of the plurality of current sources included in the first current additive DA converter circuit, each current source corresponding to a relatively high order bit is preferably composed of transistors belonging to two or more transistor groups and each current source corresponding to a relatively low order bit is preferably composed of transistors belonging to one transistor group.

Moreover, in the first current driving apparatus, interconnections used for constructing the first current source are preferably provided in an uppermost interconnect layer.

The second current driving apparatus of this invention for driving a display panel in which display brightness is controlled in accordance with the quantity of current, includes a plurality of output terminals for supplying a current to the display panel; a plurality of first transistor groups respectively including a given number of transistors used for constructing current sources of a plurality of current additive DA converter circuits and respectively disposed correspondingly to the plurality of output terminals; and a plurality of second transistor groups respectively including a given number of transistors used for constructing a current source which constructs a current mirror together with the current sources of the plurality of current additive DA converter circuits, and at least one of the plurality of current additive DA converter circuits includes a current source composed of transistors belonging to at least one of the plurality of first transistor groups and transistors belonging to at least one of the plurality of second transistor groups.

According to the second current driving apparatus, the current source of at least one current additive DA converter circuit is composed of the transistors belonging to at least one of the plurality of first transistor groups for the current additive DA converter circuits and transistors belonging to at least one of the plurality of second transistor groups for the current source circuit which constructs the current mirror with the current sources of the current additive DA converter circuits. Therefore, even when the characteristic is varied among the transistor groups, the characteristic variation is averaged for the performance of the current source. Accordingly, the output current value can be prevented from being largely different from those of the other current sources, so that the display quality uniformity of the display panel can be improved.

In the second current driving apparatus, the transistors belonging to the plurality of first transistor groups and the transistors belonging to the plurality of second transistor groups are preferably equal in width and length thereof.

The method of this invention for fabricating a current driving apparatus including a plurality of current additive DA converter circuits, which respectively include first through Kth current sources provided correspondingly to respective bits of an input signal with K (wherein K is an integer of two or more) bits and each composed of transistors in the number according to a corresponding bit, includes a first step of arranging, in rows, transistors used for constructing an ith (wherein i is a constant not less than 1 and not more than K) current source as a plurality of transistor groups each composed of transistors in a given number M (wherein M is a natural number) according to an ith bit; a second step of respectively allocating the plurality of transistor groups to the plurality of current additive DA converter circuits; and a third step of exchanging allocation of some transistors between a mth transistor group (wherein m is a natural number of 1 through n and n≧2) and a (m+n)th transistor group.

According to the method for fabricating a current driving apparatus, the allocation of some transistors is exchanged between the mth and the (m+n)th transistor groups out of the plurality of transistor groups respectively allocated to the plurality of current additive DA converter circuits. Therefore, even when the characteristic is varied among the transistor groups, the characteristic variation is averaged for the performance of the current source of the current additive DA converter circuit. Accordingly, variation of the output current value among the current additive DA converter circuits can be suppressed, so that the display quality uniformity of the display panel can be improved.

In the method for fabricating a current driving apparatus, the number of transistors exchanged in the allocation in the third step is preferably M/2.

Also, the method for fabricating a current driving apparatus preferably further includes a fourth step of exchanging allocation of some transistors between a (m+2n)th transistor group and a (m+3n)th transistor group; and a fifth step of exchanging allocation of remaining transistors not having been exchanged between a (2n)th transistor group and a (2n+1)th transistor group.

Furthermore, the method for fabricating a current driving apparatus preferably further includes a fourth step of exchanging allocation of at least part of transistors not having been exchanged between the (m+n)th transistor group and a (m+2n)th transistor group.

Moreover, in the method for fabricating a current driving apparatus, it is preferred that the number of transistors exchanged in the allocation in the third step is M/3 and that the number of transistors exchanged in the allocation in the fourth step is M/3. Alternatively, it is preferred that the number of transistors exchanged in the allocation in the third step is M/4, that the number of transistors exchanged in the allocation in the fourth step is M/4, and that the method further comprises a fifth step of exchanging allocation of M/4 transistors out of transistors not having been exchanged between the (m+n)th transistor group and a (m+3n)th transistor group.

As described above, the allocation of the transistors used for constructing the current sources is exchanged among the current additive DA converter circuits according to this invention. Therefore, even when the characteristic of the transistors is varied due to variation in dope implantation in the diffusion process or the like, influence of the characteristic variation on the output current characteristic can be reduced, so that the display ununiformity derived from the variation of current values among output terminals can be suppressed and improved.

Thus, according to the current driving apparatus of the invention, the output current characteristic variation is averaged by exchanging the allocation of the transistors used for constructing the current sources. Accordingly, the output characteristic of the current driving apparatus can be improved without modifying the diffusion process, and thus, display unevenness of the display panel such as an organic EL panel can be reduced.

### BRIEF DESCRIPTION OF THE DRAWINGS

FIG. 1 is a diagram of an exemplified layout of a current source included in a DA converter circuit of a current driving apparatus according to an embodiment of the invention;

FIG. 2 is a schematic diagram of an example of a pattern for exchanging allocation of transistors;

FIG. 3 is a schematic diagram of another example of the pattern for exchanging the allocation of the transistors;

FIG. 4 is a schematic diagram of still another example of the pattern for exchanging the allocation of the transistors;

FIGS. 5A and 5B are graphs for showing an effect attained by the embodiment of the invention;

FIG. 6 is a schematic diagram of another example of the pattern for exchanging the allocation of the transistors;

FIG. 7 is a diagram of exemplified layout and wiring for a DA converter circuit of FIG. 6;

FIG. 8 is a diagram of another exemplified layout and wiring for the DA converter circuit of FIG. 6;

FIG. 9 is a schematic diagram of an example of the pattern for exchanging the allocation of every third part of transistors;

FIG. 10 is a schematic diagram of an example of the pattern for exchanging the allocation of every fourth part of transistors;

FIG. 11 is a diagram of exemplified exchange in which the allocation of transistors of merely current sources corresponding to high order bits is exchanged;

FIG. 12A is a diagram of an exemplified configuration of a current source circuit and FIG. 12B is a diagram of exemplified exchange of transistor allocation including transistors of the current source circuit;

FIGS. 13A and 13B are diagrams for showing exemplified configurations of a conventional current driving apparatus and a current driving apparatus of the embodiment;

FIG. 14 is a diagram for showing an example of arrangement in a conventional DA converter circuit; and

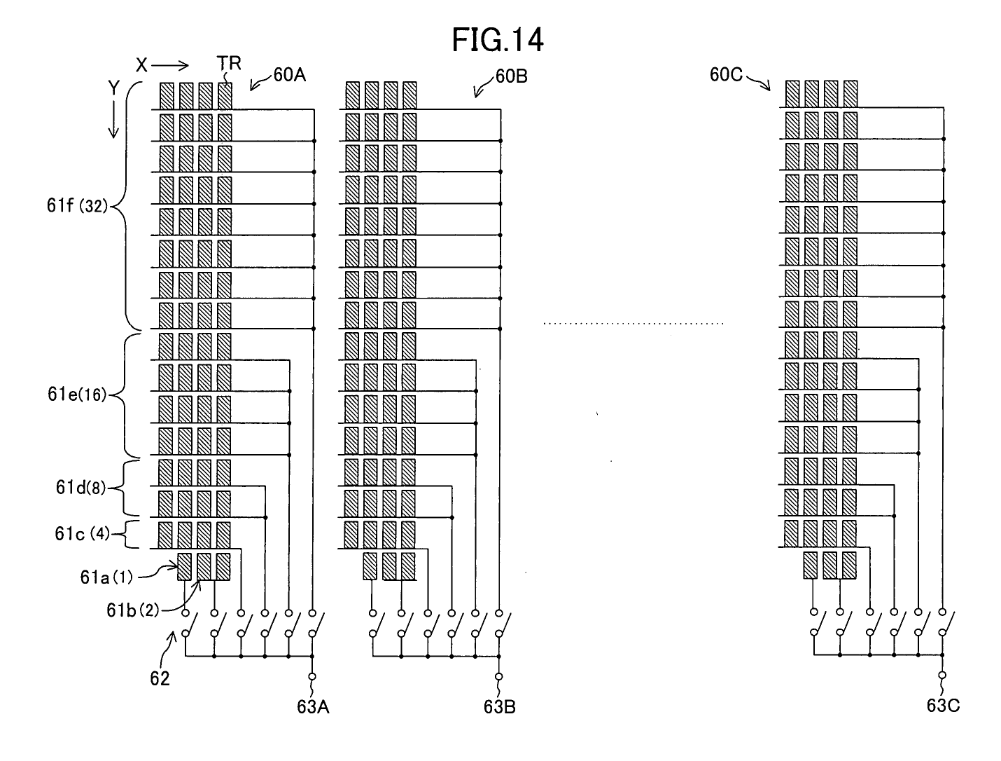

FIG. 15 is a graph for showing variation of the current characteristic of the conventional current driving apparatus.

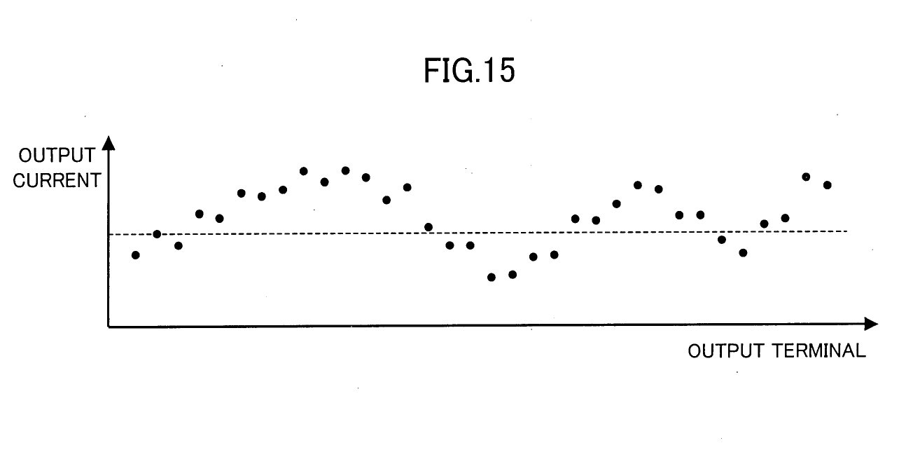

### DETAILED DESCRIPTION OF THE INVENTION

A preferred embodiment of the invention will now be described with reference to the accompanying drawings.

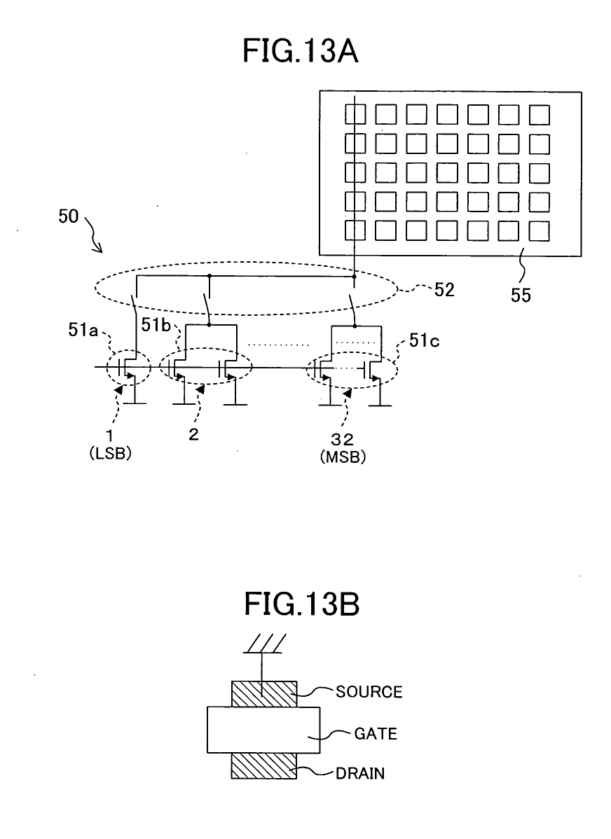

A current driving apparatus of this embodiment basically has the architecture shown in FIG. 13, whereas the layout of current sources included in a current additive DA converter circuit (hereinafter simply referred to as the “DA converter circuit”) is different from the conventional layout.

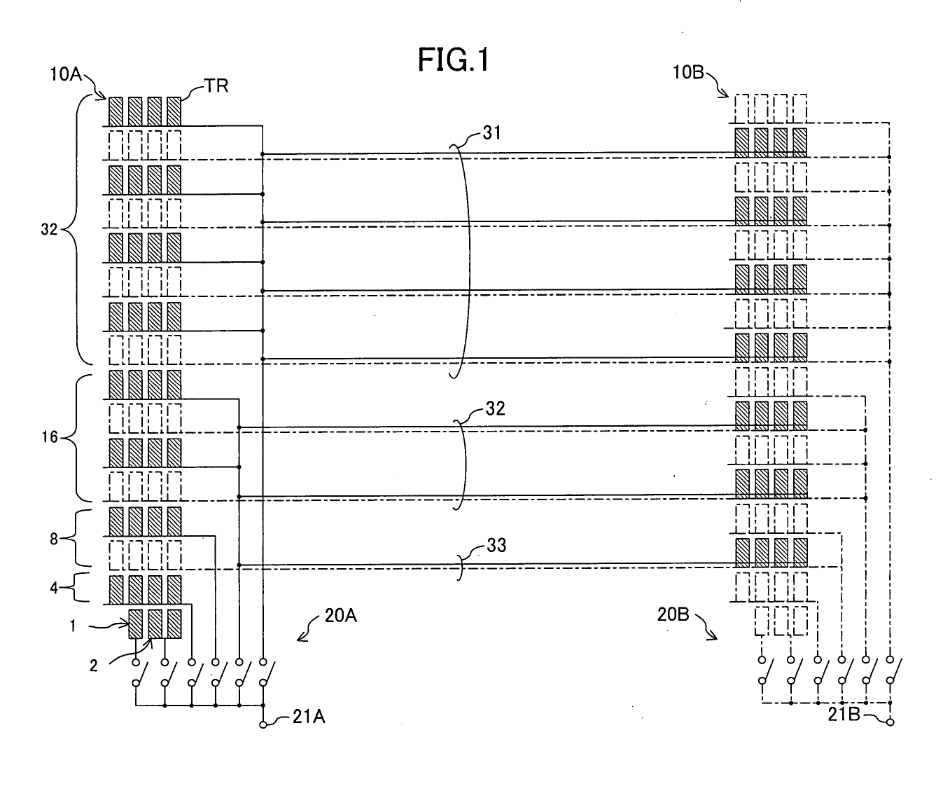

FIG. 1 shows an example of the layout of current sources included in DA converter circuits of the current driving apparatus of this embodiment. In FIG. 1, a first transistor group 10A and a second transistor group 10B are disposed respectively correspondingly to a plurality of output terminals 21A and 21B. Each of the first and second transistor groups 10A and 10B is composed of thirty-two transistors TR used for constructing a current source corresponding to the most significant bit (i.e., the sixth bit), sixteen transistors TR used for constructing a current source corresponding to the fifth bit, and eight, four, two and one transistors TR respectively used for constructing current sources corresponding to the fourth, third, second and first bits.

In FIG. 1, allocation of some of the transistors used for constructing the current sources is exchanged between a first DA converter circuit 20A and a second DA converter circuit 20B. For example, the current source corresponding to the most significant bit of the first DA converter circuit 20A is composed of sixteen transistors disposed on the first, third, fifth and seventh rows of the first transistor group 10A and sixteen transistors disposed on the second, fourth, sixth and eighth rows of the second transistor group 10B adjacent to the first transistor group 10A. On the other hand, the current source corresponding to the most significant bit of the second DA converter circuit 20B is composed of sixteen transistors disposed on the second, fourth, sixth and eighth rows of the first transistor group 10A and sixteen transistors disposed on the first, third, fifth and seventh rows of the second transistor group 10B. For exchanging the allocation of the transistors in this manner, interconnections 31, 32 and 33 are provided.

In the conventional layout, each current source of the first DA converter circuit 20A is composed of the transistors belonging to the first transistor group 10A and each current source of the second DA converter circuit 20B is composed of the transistors belonging to the second transistor group 10B. In contrast, since the allocation of the transistors used for constructing the current sources of the first and second DA converter circuits 20A and 20B is mutually exchanged as shown in FIG. 1 in this embodiment, even when the characteristics of the transistors are different between the first transistor group 10A and the second transistor group 10B, the difference in the characteristic is averaged, resulting in outputting uniform currents.

The interconnections 31, 32 and 33 provided for exchanging the allocation of the transistors are preferably provided in the uppermost interconnect layer. Thus, even when a long interconnect is necessary for the exchange, signal delay derived from the parasitic capacitance of the interconnect can be prevented. Specifically, an interconnect layer disposed in an upper position generally tends to have smaller parasitic capacitance because it is away from a substrate together with which the capacitance is formed. Therefore, when the interconnections used for the exchange are provided in the uppermost interconnect layer having smaller parasitic capacitance, rapid conversion can be realized in transition of the dynamic operation of the DA converter circuits.

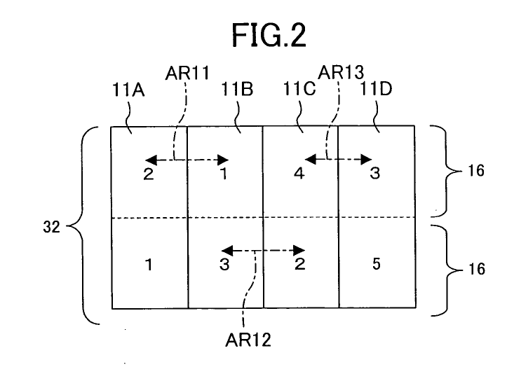

FIG. 2 is a schematic diagram for showing an example of a pattern for exchanging the allocation of the transistors used for constructing the current sources. In FIG. 2, reference numerals 11A, 11B, 11C and 11D denote transistor groups used for constructing current sources corresponding to the six bits of DA converter circuits, and it is assumed that thirty-two transistors are arranged in each transistor group in the form a matrix of four in the X direction by eight in the Y direction. Also, the numerical value provided in each rectangle denoting the transistor group is a number for identifying the DA converter, and an arrow indicates exchange of the allocation of the transistors used for constructing the current sources.

For example, an arrow AR11 means that the allocation of sixteen transistors is exchanged between the first transistor group 11A and the second transistor group 11B. Owing to this exchange, the current source of a first DA converter circuit, which was originally composed of the transistors belonging to the first transistor group 11A alone, is composed of sixteen transistors belonging to the first transistor group 11A and sixteen transistors belonging to the second transistor group 11B.

Similarly, the allocation of sixteen transistors is exchanged between the second and third transistor groups 11B and 11C (as shown with an arrow AR12), and the allocation of sixteen transistors is exchanged between the third and fourth transistor groups 11C and 11D (as shown with an arrow AR13). As a result, the current source of a second DA converter circuit is composed of sixteen transistors belonging to the first transistor group 11A and sixteen transistors belonging to the third transistor group 11C, and the current source of a third DA converter circuit is composed of sixteen transistors belonging to the second transistor group 11B and sixteen transistors belonging to the fourth transistor group 11D.

By exchanging the allocation of the transistors as shown in FIG. 2, the characteristics of the transistors used for constructing the current sources of the respective DA converter circuits are averaged, so that more uniform currents can be output. Also, since the transistor allocation is exchanged between the DA converter circuits close to each other, characteristic variation with a comparatively small cycle can be averaged. Furthermore, since the number of transistors to be exchanged corresponds to a half of the number of transistors included in each current source, the exchange can be well balanced, and hence, the display uniformity can be further improved.

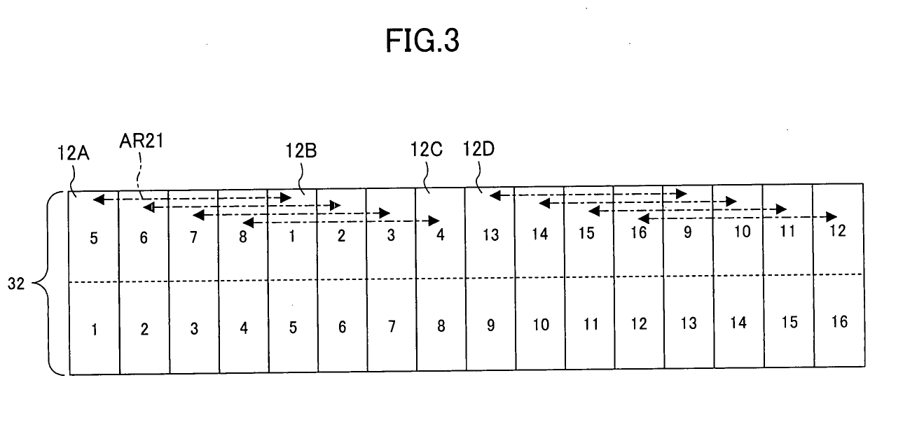

FIG. 3 is a schematic diagram for showing another example of the pattern for exchanging the allocation of transistors used for constructing current sources. Similarly to FIG. 2, each rectangle indicates a transistor group composed of thirty-two transistors arranged in the form of an array, a numerical value shown within the rectangle indicating the transistor group is a number for identifying a DA converter circuit, and an arrow means exchange of the allocation of transistors used for constructing the current sources.

In the example shown in FIG. 3, the allocation of a half of transistors belonging to each transistor group (namely, sixteen transistors) is exchanged between transistor groups spaced from each other at an interval of three transistor groups. For example, the allocation of the transistors is exchanged between a transistor group 12A and a transistor group 12B spaced from the transistor group 12A at an interval of three transistor groups (namely, with the other three transistor groups disposed therebetween) (as shown with an arrow AR21). Thus, a current source of a first DA converter circuit is composed of sixteen transistors belonging to the transistor group 12A and sixteen transistors belonging to the transistor group 12B, and a current source of a fifth DA converter circuit is composed of the remaining sixteen transistors belonging to the transistor group 12A and the remaining sixteen transistors belonging to the transistor group 12B.

In the same manner as in FIG. 3, the allocation can be exchanged between transistor groups spaced from each other at an interval of n (wherein n is a natural number) transistor groups. Thus, characteristic variation having a comparatively large cycle can be averaged. Also, in the example shown in FIG. 3, out of the transistors originally allocated to the current source of each DA converter circuit, the allocation of a half of the transistors is exchanged but the allocation of the other transistors is not exchanged, and therefore, a region necessary for interconnections used for the exchange can be small.

In the example shown in FIG. 3, the transistor allocation is not exchanged between a portion corresponding to the transistor group 12C and preceding transistor groups and a portion corresponding to the transistor group 12D and following transistor groups. Therefore, a level difference may occur in the output current characteristic between these portions where the allocation is not exchanged, namely, between an eighth DA converter circuit and a ninth DA converter circuit.

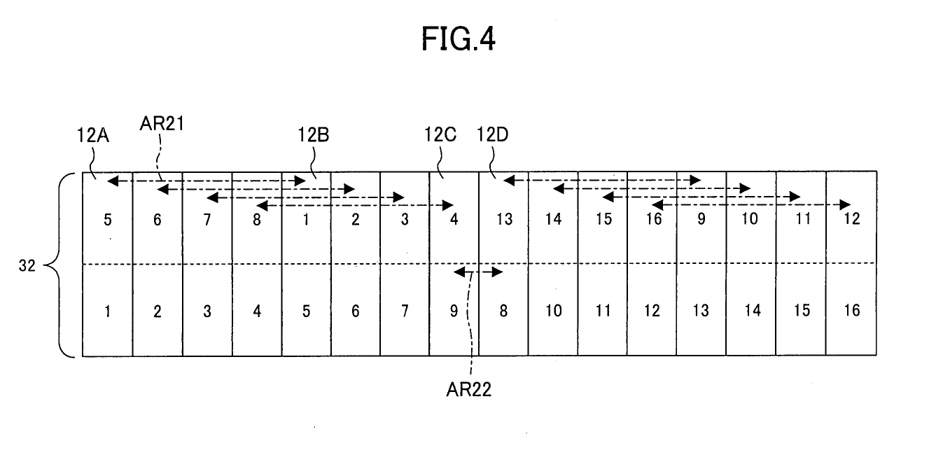

In order to prevent the occurrence of such a level difference, the allocation of transistors is exchanged between a transistor group 12C and a transistor group 12D (as shown with an arrow AR22) in an example shown in FIG. 4. Thus, the portions between which transistor allocation is not exchanged can be eliminated, resulting in smoothing the current characteristic change.

The layout as shown in FIG. 3 can be realized by the following fabrication method: It is herein assumed that an input signal of each DA converter circuit has K bits. First, transistors used for constructing a current source corresponding to an ith (wherein i is a constant not less than 1 and not more than K) are arranged in rows as a plurality of transistor groups each composed of transistors in a certain number M (wherein M is a natural number) according to the ith bit (in a first step). In FIG. 3, transistors used for constructing the current source corresponding to the sixth bit are arranged as a plurality of transistor groups each composed of thirty-two transistors. Then, the respective transistor groups are successively once allocated to respective DA converter circuits (in a second step). The procedures up to this point are the same as those of a conventional fabrication method.

Thereafter, in these transistor groups, the allocation of some transistors is exchanged between an mth (wherein m is a natural number of 1 through n and n≧2) transistor group and a (m+n)th transistor group (in a third step). In the example shown in FIG. 3, the allocation of the sixteen transistors is exchanged between a mth (m=1 through 4) transistor group and a (m+4)th transistor group.

Furthermore, between a (m+2n)th transistor group and a (m+3n)th transistor group, the allocation of some transistors is exchanged (in a fourth step). In the example shown in FIG. 3, the allocation of the sixteen transistors is exchanged between a (m+8)th transistor group and a (m+12) the transistor group. Furthermore, between a (2n)th transistor group and a (2n+1)th transistor group, the allocation of the remaining transistors not having been exchanged is exchanged (in a fifth step). In the example shown in FIG. 4, the allocation of the remaining sixteen transistors is exchanged between the eighth transistor group and the ninth transistor group.

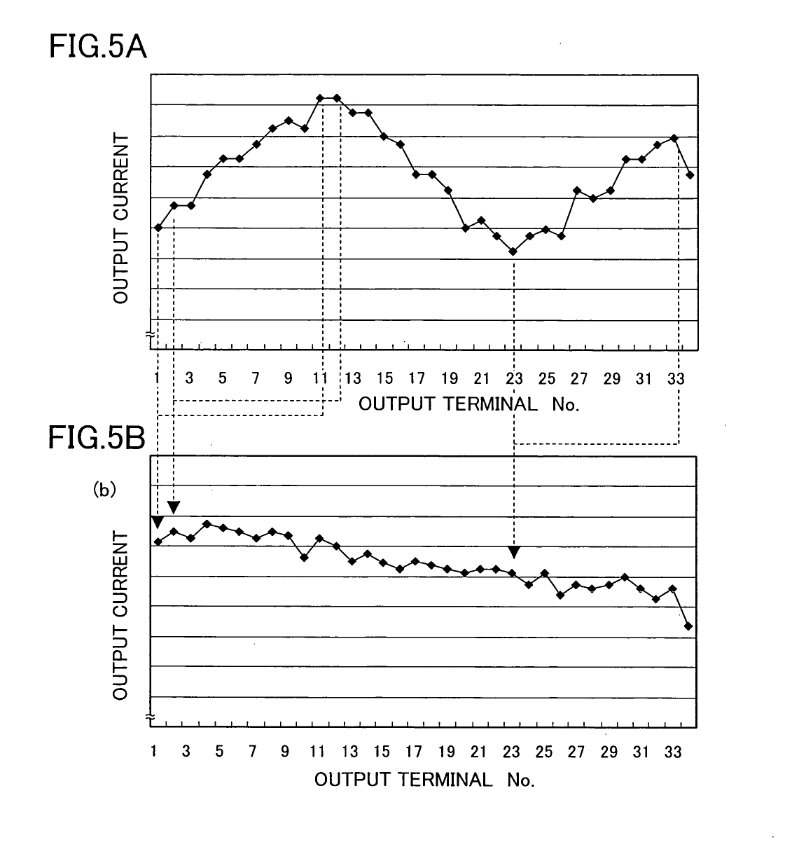

FIGS. 5A and 5B are graphs for showing improvement of the variation of the output current characteristic according to this embodiment. FIG. 5A shows the output current characteristic obtained in the conventional technique and FIG. 5B shows the output current characteristic obtained according to the embodiment in which the allocation of transistors is exchanged between transistor groups spaced from each other at an interval of nine transistor groups. As shown in FIG. 5A, in the conventional technique, the output current characteristic is largely varied among output terminals owing to variation caused in, for example, diffusion process. On the other hand, as shown in FIG. 5B, according to the embodiment, even though the diffusion process itself is not improved, the characteristic variation among the output terminals is averaged and the change of the output currents is smooth.

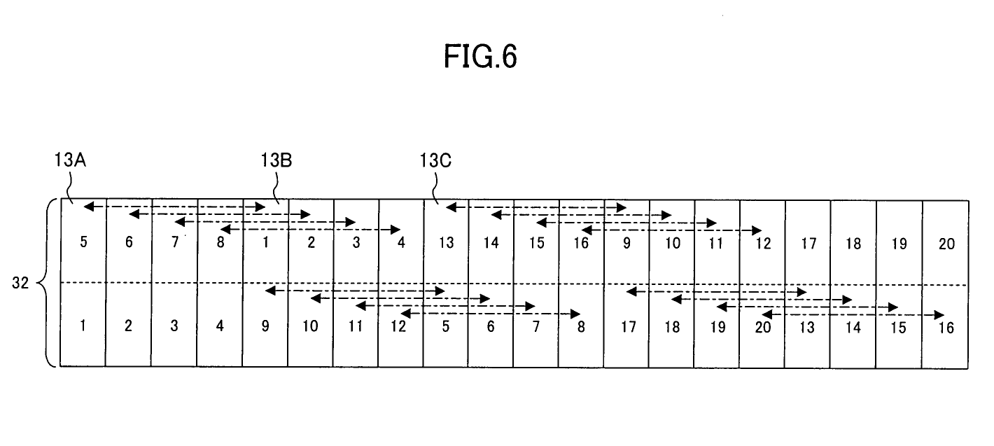

FIG. 6 is a schematic diagram for showing another example of the pattern for exchanging the allocation of transistors used for constructing current sources. Each rectangle, each numerical value shown in the rectangle and each arrow are used in the same manner as in FIG. 2. In the example shown in FIG. 6, the allocation of a half of transistors (namely, sixteen transistors) is exchanged between transistor groups spaced from each other at an interval of three transistor groups. For example, the allocation of transistors is exchanged between a transistor group 13A and a transistor group 13B spaced from each other at an interval of three transistor groups. Furthermore, in the transistor group 13B and following transistor groups, the allocation of remaining transistors is also exchanged with that of another transistor group spaced in the other direction at an interval of three transistor groups. For example, the allocation of the remaining sixteen transistors of the transistor group 13B is exchanged with that of a transistor group 13C.

For example, a fifth DA converter circuit was originally composed of the transistor group 13B corresponding to the output terminal of the fifth DA converter circuit. However, through the exchange of the transistor allocation as shown in FIG. 6, it is composed of the transistors belonging to the transistor groups 13A and 13C spaced from the transistor group 13B at an interval of three transistor groups. Specifically, each current source is composed of transistors belonging to two transistor groups spaced from the corresponding output terminal by a substantially equal distance. Each current source of the other sixth through sixteenth DA converter circuits is similarly configured. Owing to such an architecture, the current characteristic variation among a large number of output terminals can be smoothly averaged.

The layout as shown in FIG. 6 can be realized by exchanging the allocation of at least a part of the remaining transistors not having been exchanged between a (m+n)th transistor group and a (m+2n)th transistor group (in a fourth step) after the aforementioned third step. In the example shown in FIG. 6, the allocation of the remaining sixteen transistors not having been exchanged is exchanged between a (m+4)th transistor group and a (m+8)th transistor group.

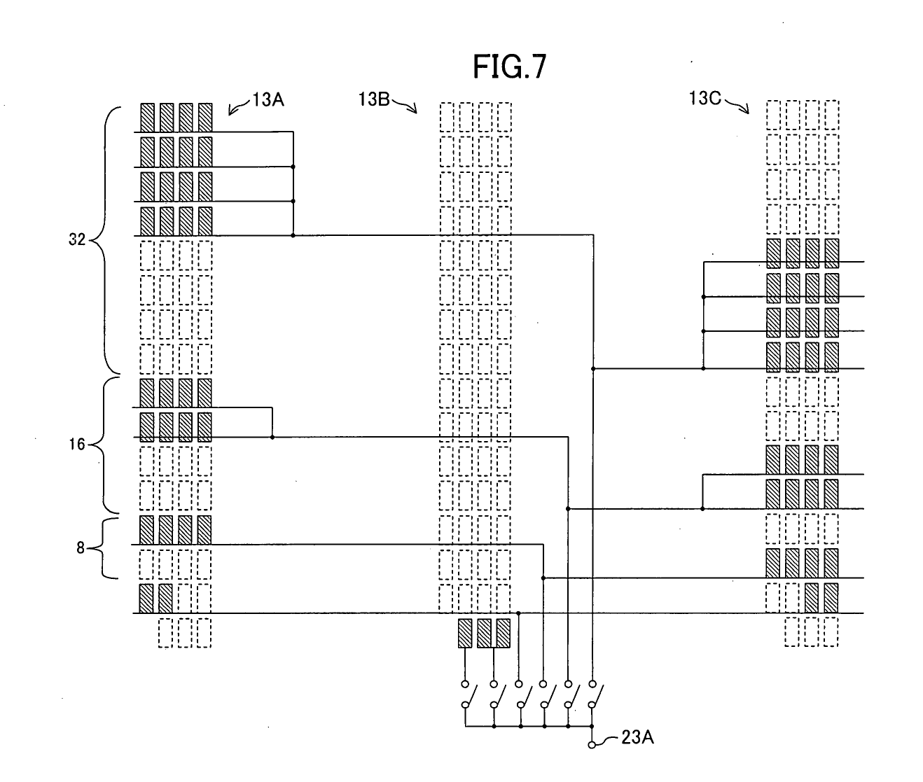

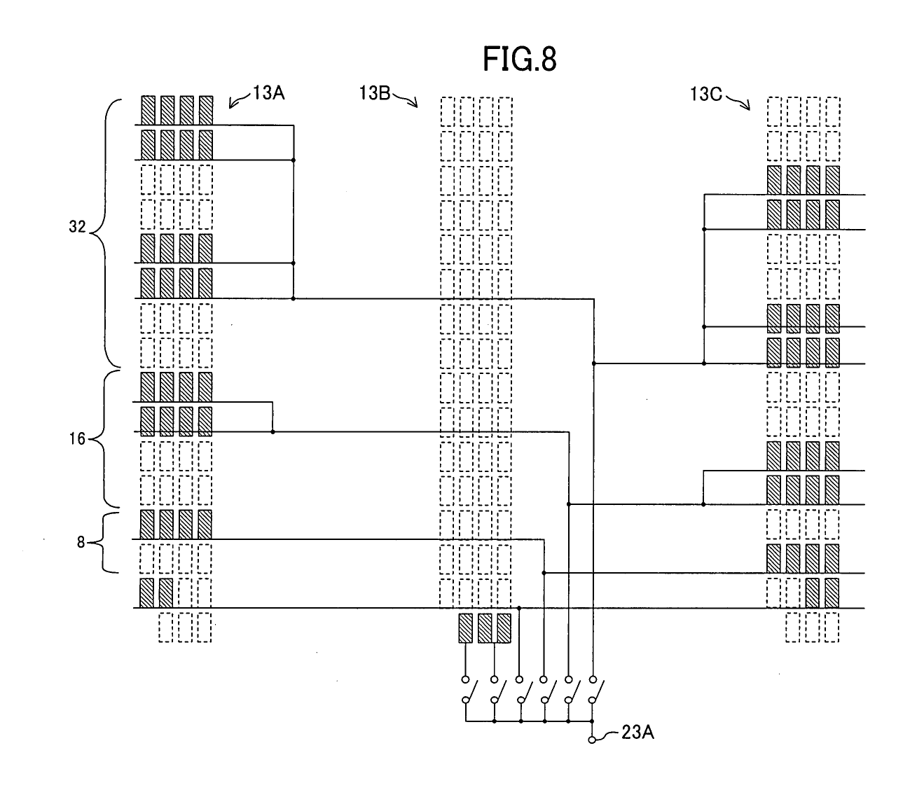

FIGS. 7 and 8 show examples of the layout and wiring of the DA converter circuit shown in the example of FIG. 6. FIGS. 7 and 8 show a fifth DA converter circuit including a current source composed of transistors belonging to transistor groups 13A and 13C. In the example of FIG. 7, a current source corresponding to the sixth bit is composed of sixteen transistors arranged in the first through fourth rows of the transistor group 13A and sixteen transistors arranged in the fifth through eighth rows of the transistor group 13C. On the other hand, in the example of FIG. 8, the current source corresponding to the sixth bit is composed of sixteen transistors arranged in the first, second, fifth and sixth rows of the transistor group 13A and sixteen transistors arranged in the third, fourth, seventh and eighth rows of the transistor group 13C.

In the case where one current source is composed of transistors belonging to a plurality of transistor groups, the transistors belonging to the respective transistor groups used for constructing the current source are preferably not in the same relative positions in the layout. Assuming that the direction for arranging the transistor groups corresponds to the X axis and the direction perpendicular to the arrangement of the transistor groups corresponds to the Y direction, “the same relative positions” means that the transistors used for constructing the current source have the same Y coordinate (but naturally have different X coordinates). In each of the examples shown in FIGS. 1, 7 and 8, the allocation of the thirty-two transistors used for constructing the current source corresponding to the sixth bit is exchanged so that these transistors cannot be in the same relative positions in the layout, namely, they have different Y coordinates.

This is application of what is called a common centroid structure to the current driving apparatus. Specifically, when the allocation of transistors different in both the X coordinate and the Y coordinate is exchanged, the transistor allocation is exchanged in the orthogonal direction in a sense. Therefore, the influence of deviation in the transistor characteristic derived from the position can be further reduced, so as to further average the output current variation.

In the above-described examples, each current source of a DA converter circuit is composed of transistors belonging to two transistor groups. The characteristic variation is averaged by employing such an architecture, and for attaining more stable characteristic variation, the current source is preferably composed of transistors belonging to a large number of transistor groups.

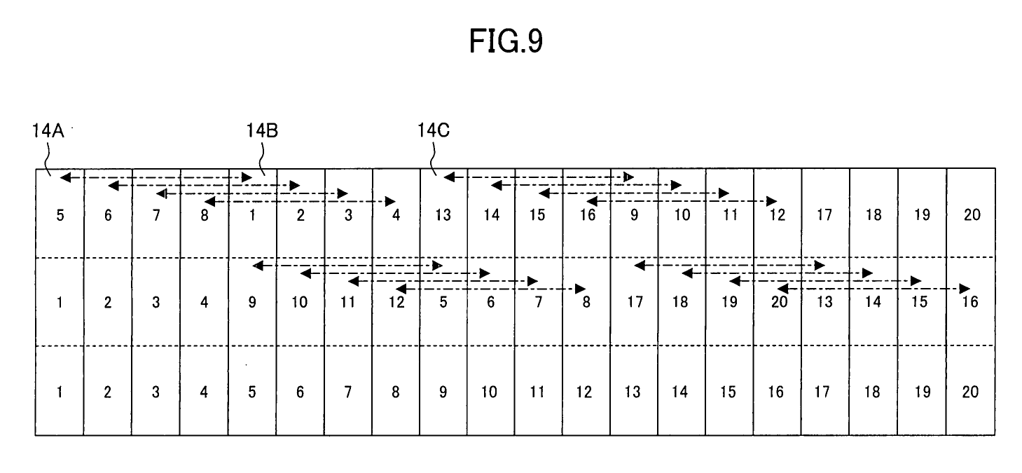

Therefore, in an example shown in FIG. 9, the allocation of transistors of each transistor group is exchanged by every third group. The exchange is performed in the same manner as in FIG. 6. For example, with respect to a transistor group 14B, one-third of transistors are exchanged with one-third of transistors of a transistor group 14A, another one-third of transistors are exchanged with one-third of a transistor group 14C, and the remaining one-third of transistors are not exchanged. Thus, a current source of a fifth DA converter circuit is composed of the transistors belonging to the three transistor groups 14A, 14B and 14C. Current sources of sixths through sixteenth DA converter circuits are configured in a similar manner. The output current variation can be further reduced by employing such an architecture. In addition, since the remaining transistors not exchanged are those originally used for the current source, the number of interconnections newly provided for the exchange is smaller than in the example shown in FIG. 6.

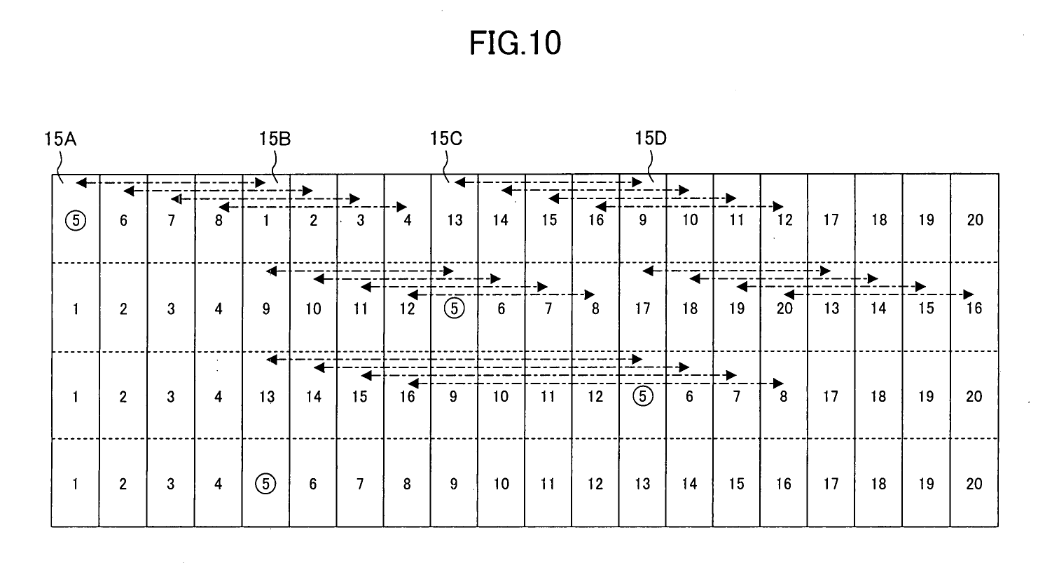

Alternatively, in an example shown in FIG. 10, the allocation of transistors of each transistor group is exchanged by every fourth part. For example, with respect to a transistor group 15B, one-fourth of transistors are exchanged with one-fourth of transistors of a transistor group 15A, another one-fourth of transistors are exchanged with one-fourth of transistors of a transistor group 15C, another one-fourth of transistors are exchanged with one-fourth of transistors of a transistor group 15D, and the remaining one-fourth of transistors are not exchanged. Thus, a current source of a fifth DA converter circuit is composed of the transistors belonging to the four transistor groups 15A, 15B, 15C and 15D. Current sources of sixth through sixteenth DA converter circuits are configured in a similar manner.

The output current variation can be further reduced by employing such an architecture. In addition, the remaining transistors not exchanged are those originally used for the current source, and hence, the number of interconnections newly provided for the exchange is small. Moreover, a current driving apparatus of a display panel is generally provided with display data of a binary number, and hence, each current source is composed of transistors in the number equal to a power of two, such as sixteen or thirty-two, as described above. Therefore, when transistors of each transistor group are exchanged by every fourth part, the layout can be eased.

The aforementioned exchange of the transistor allocation may be executed on all or some of the current sources corresponding to respective bits. When the allocation of transistors is exchanged in the current sources corresponding to all the bits, the linearity characteristic of gray scale is improved and an arbitrary gray scale current is averaged, so that the display quality can be improved.

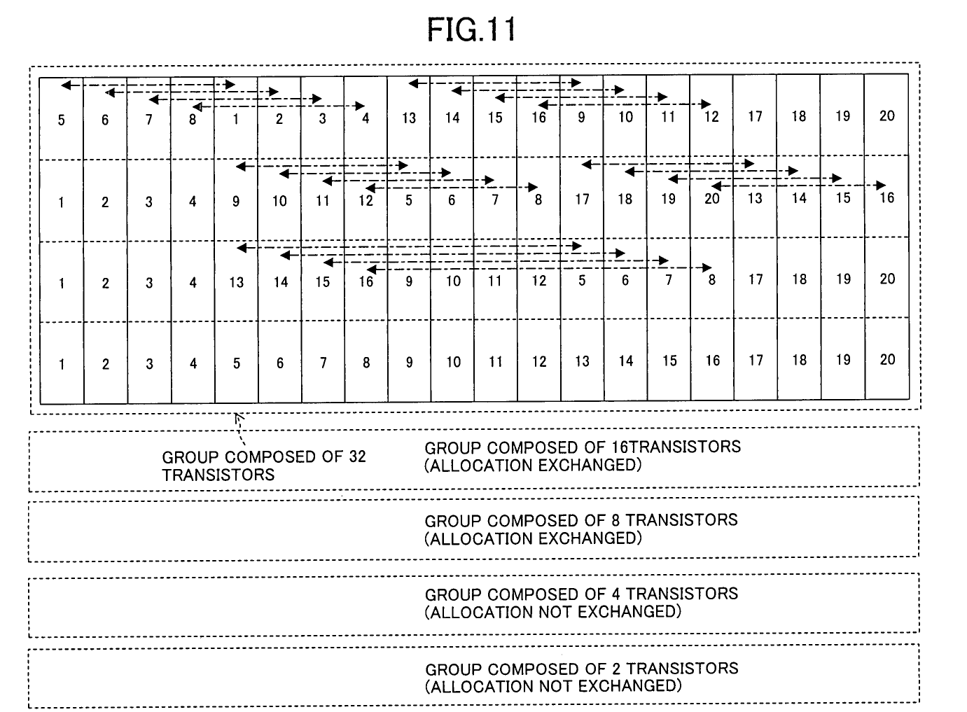

On the other hand, in an example shown in FIG. 11, the transistor allocation is not exchanged in current sources corresponding to relatively low order bits (that is, the first through third bits in this example) but is exchanged merely in current sources corresponding to relatively high order bits (that is, the fourth through sixth bits in this example). For example, in a display panel with comparatively low display quality, data of low order bits is less significant, and hence, the display quality is less possibly spoiled even when the current characteristic corresponding to the low order bits is rather varied. Therefore, the allocation of transistors is not exchanged with respect to the low order bits less affecting the display quality, so as to ease wiring and reinforce power interconnections or the like instead. Thus, a highly practical current driving apparatus can be realized.

The exchange of the transistor allocation in current sources included in a DA converter circuit has been described so far. Furthermore, allocation of transistors including those of the current source circuit which constructs the current mirror with the current sources of the DA converter circuit may be exchanged.

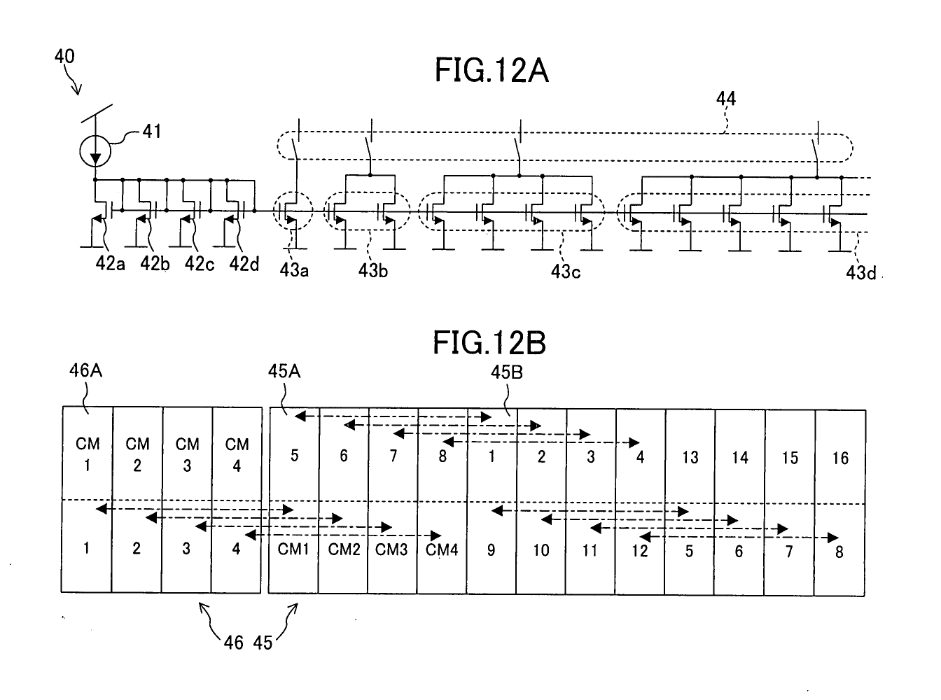

FIG. 12A is a circuit diagram for showing the configuration of a current source circuit included in the current driving apparatus of this embodiment. In FIG. 12A, the current source circuit 40 includes a reference current source 41 and a plurality of transistors 42a through 42d diode-connected to each other. The reference current source 41 may be provided inside a semiconductor integrated circuit of the current driving apparatus or may be externally provided.

The transistors 42a through 42d are N-type transistors of the same size, are grounded at their sources and are supplied with a current from the reference current source 41 at their drains and gates. Since the current is supplied from the reference current source 41 to the drain of each transistor, potential is generated on the gate thereof. This gate potential is determined depending upon the number of connected transistors. The gate potential generated by the current source circuit 41 is supplied to transistors used for constructing current sources 43a through 43d of each DA converter circuit. A switch group 44 selects outputs of the current sources 43a through 43d.

FIG. 12B is a schematic diagram for showing an example where the allocation of the transistors including those used for constructing the current source circuit is exchanged. In FIG. 12B, a reference numeral 45 denotes a plurality of first transistor groups provided correspondingly to respective output terminals and each including a given number of transistors used for constructing current sources of the DA converter circuits, and a reference numeral 46 denotes a plurality of second transistor groups each including a given number of transistors used for constructing the current source circuit. Also, CM1 through CM4 denote transistors used for constructing a bias circuit of a current mirror included in the current source circuit.

In the example shown in FIG. 12B, the allocation of the transistors including those of the current source circuit is exchanged. For example, a first DA converter circuit, whose current source was originally to be composed of a transistor group 45A, has a current source composed of a transistor group 45B out of the plural first transistor groups 45 and a transistor group 46A out of the plural second transistor groups 46. The pattern for exchanging the allocation of the transistors is not limited to that shown in FIG. 12B but may be any of various patterns including the aforementioned examples.

When such an architecture is employed, the characteristic variation of the transistors including those of the current source circuit which constructs the current mirror with the current sources of the DA converter circuits can be averaged, and hence, the output current variation can be further reduced. In particular, in the case where a display panel includes a plurality of different current driving apparatuses, uniform output currents can be obtained by utilizing a common reference current source 41 for the respective current driving apparatuses.

It is noted that transistors belonging to the plural first transistor groups 45 and the plural second transistor groups 46 preferably have the same width and the same length. Thus, the transistor allocation can be easily exchanged. However, when their widths and lengths are in the relationship of, for example, integral multiple, approximate characteristics can be obtained by determining the number of transistors to be selected for the exchange so as to make the total width and length of the selected transistors the same. Also in this case, a current driving apparatus in which the transistor characteristic variation is reduced can be obtained.

1. A current driving apparatus for driving a display panel in which display brightness is controlled in accordance with the quantity of current, comprising:
a plurality of output terminals each for supplying a current to said display panel; and
a plurality of transistor groups respectively disposed correspondingly to said plurality of output terminals and respectively including a given number of transistors used for constructing current sources of a plurality of current additive DA converter circuits for respectively supplying currents to said plurality of output terminals,
wherein a first current additive DA converter circuit that is at least one of said plurality of current additive DA converter circuits includes a first current source composed of transistors belonging to at least two of said plurality of transistor groups.

2. The current driving apparatus of claim 1,
wherein said first current source is composed of transistors belonging to first and second transistor groups of said plurality of transistor groups.

3. The current driving apparatus of claim 2,
wherein said first current source is composed of M (wherein M is a natural number) transistors, and
said M transistors include M/2 transistors belonging to said first transistor group and M/2 transistors belonging to said second transistor group.

4. The current driving apparatus of claim 2,
wherein said first transistor group and said second transistor group are arranged adjacently to each other.

5. The current driving apparatus of claim 2,
wherein said plurality of transistor groups are arranged in rows, and
said first transistor group and said second transistor group are spaced from each other at an interval of a given number of transistor groups.

6. The current driving apparatus of claim 1,
wherein each of said plurality of current additive DA converter circuits includes a plurality of current sources provided correspondingly to respective bits of an input signal and each composed of a given number of transistors in the number according to a corresponding bit,
each of all or some of a plurality of current sources including said first current source provided in said first current additive DA converter circuit is composed of transistors belonging to at least two of said plurality of transistor groups.

7. The current driving apparatus of claim 6,
wherein out of said plurality of current sources included in said first current additive DA converter circuit, each current source corresponding to a relatively high order bit is composed of transistors belonging to two or more transistor groups and each current source corresponding to a relatively low order bit is composed of transistors belonging to one transistor group.

8. The current driving apparatus of claim 1,
wherein interconnections used for constructing said first current source are provided in an uppermost interconnect layer.

9. A current driving apparatus for driving a display panel in which display brightness is controlled in accordance with the quantity of current, comprising:
a plurality of output terminals each for supplying a current to said display panel;
a plurality of first transistor groups respectively including a given number of transistors used for constructing current sources of a plurality of current additive DA converter circuits and respectively disposed correspondingly to said plurality of output terminals; and
a plurality of second transistor groups respectively including a given number of transistors used for constructing a current source circuit which constructs a current mirror together with said current sources of said plurality of current additive DA converter circuits,
wherein at least one of said plurality of current additive DA converter circuits includes a current source composed of transistors belonging to at least one of said plurality of first transistor groups and transistors belonging to at least one of said plurality of second transistor groups.

10. The current driving apparatus of claim 9,
wherein said transistors belonging to said plurality of first transistor groups and said transistors belonging to said plurality of second transistor groups are equal in width and length thereof.

11. A method for fabricating a current driving apparatus including a plurality of current additive DA converter circuits, which respectively include first through Kth current sources provided correspondingly to respective bits of an input signal with K (wherein K is an integer of two or more) bits and each composed of transistors in the number according to a corresponding bit, comprising:
a first step of arranging, in rows, transistors used for constructing an ith (wherein i is a constant not less than 1 and not more than K) current source as a plurality of transistor groups each composed of transistors in a given number M (wherein M is a natural number) according to an ith bit;
a second step of respectively allocating said plurality of transistor groups to said plurality of current additive DA converter circuits; and
a third step of exchanging allocation of some transistors between a mth transistor group (wherein m is a natural number of 1 through n and n≧2) and a (m+n)th transistor group.

12. The method of claim 11,
wherein the number of transistors exchanged in the allocation in the third step is M/2.

13. The method of claim 11, further comprising:
a fourth step of exchanging allocation of some transistors between a (m+2n)th transistor group and a (m+3n)th transistor group; and
a fifth step of exchanging allocation of remaining transistors not having been exchanged between a (2n)th transistor group and a (2n+1)th transistor group.

14. The method of claim 11, further comprising a fourth step of exchanging allocation of at least part of transistors not having been exchanged between the (m+n)th transistor group and a (m+2n)th transistor group.

15. The method of claim 14,
wherein the number of transistors exchanged in the allocation in the third step is M/3, and
the number of transistors exchanged in the allocation in the fourth step is M/3.

16. The method of claim 14,
wherein the number of transistors exchanged in the allocation in the third step is M/4,
the number of transistors exchanged in the allocation in the fourth step is M/4, and
the method further comprises a fifth step of exchanging allocation of M/4 transistors out of transistors not having been exchanged between the (m+n)th transistor group and a (m+3n)th transistor group.
